(19) United States
(12) Patent Application Publication
(10) Pub. No.: US 2026/0347611 A1
(43) Pub. Date: Nov. 5, 2026

(54) CURABLE SILICONE COMPOSITION, ADHESIVES, OPTICAL SEMICONDUCTOR REFLECTIVE MATERIAL AND OPTICAL SEMICONDUCTOR DEVICE

(71) Applicant: Duroptix Materials Kabushiki Kaisha, Tokyo (JP)

(72) Inventor: Xinnan Cui, Ichihara-shi (JP)

(73) Assignee: Duroptix Materials Kabushiki Kaisha, Tokyo (JP)

(21) Appl. No.: 19/667,108

(22) Filed: May 4, 2026

(30) Foreign Application Priority Data
May 2, 2025 (JP) 2025-076939

(51) Int. Cl. C08L 83/06; B01J 23/42; C08K 3/22; C08K 3/36; G02B 1/04; H10H 20/856

(52) U.S. Cl. CPC C08L 83/06; B01J 23/42; C08K 3/22; C08K 3/36; C08K 2003/2237; C08L 2203/20; C08L 2205/025; G02B 1/04; H10H 20/856

(57) ABSTRACT

A curable silicone composition is provided that is capable of forming a cured product having a low coefficient of thermal expansion. The curable silicone composition comprises: (A) an alkenyl group-containing organopolysiloxane having at least two alkenyl groups per molecule; (B) an organohydrogenpolysiloxane including at least two silicon atom-bonded hydrogen atoms per molecule; (C) silica; (D) a high boiling point organic solvent having a boiling point of 100 °C or higher; and (E) a curing catalyst.

### CROSS-REFERENCE TO RELATED APPLICATION

The present application claims priority on the basis of Japanese Patent Application No. 2025-076939, filed on May 2, 2025, the contents of which are incorporated herein by reference.

### TECHNICAL FIELD

The present disclosure relates to a curable silicone composition and, more specifically, relates to a curable silicone composition which can be advantageously used for a reflective material for optical semiconductor devices. The present disclosure also relates to: a reflective material for optical semiconductor devices, which comprises a cured product of said curable silicone composition; and an optical semiconductor device provided with said reflective material.

### BACKGROUND

When cured, curable silicone compositions form cured products having excellent heat resistance, cold resistance, electrical insulating properties, weathering resistance, water repellency and transparency, and are therefore used in a wide variety of industrial fields. In particular, if compared with other organic materials, these cured products are less prone to discoloration and undergo less deterioration of physical properties such as durability, and are therefore widely used for optical materials, and especially as mounting substrates serving as reflective materials in optical semiconductor devices such as light-emitting diodes (LEDs).

As electronic devices have become more functional, efforts have been made to achieve higher density integration and higher density mounting of electronic components, and there is a need for thinner substrates in the case of mounting substrates serving as reflective materials in optical semiconductor devices. However, if substrates are made thinner, this can cause the problem of warping in cured products as a result of heat applied during curing, and there is a need for substrates having a low coefficient of thermal expansion in order to reduce warping. Substrates containing a high proportion of inorganic fillers have been developed in the past in order to reduce the coefficient of thermal expansion of such substrates.

For example, curable resin compositions have been proposed that contain, as essential components: (A) an organic compound having at least two SiH group-reactive carbon-carbon double bonds per molecule; (B) a compound containing at least two SiH groups per molecule; (C) a hydrosilylation catalyst; (D) a silicone compound having at least one carbon-carbon double bond reactive with an SiH group per molecule; and (E) an inorganic filler.

However, in cases where an inorganic filler was contained at a high content, the viscosity of a silicone composition increased, and there was the problem that handling and moldability during curing and molding deteriorated. Therefore, there is still a need to develop a curable silicone composition capable of forming a cured product having a low coefficient of thermal expansion.

### BRIEF SUMMARY

Curable silicone compositions, reflective material for optical semiconductor devices, and optical semiconductor devices are provided herein. In an embodiment, a curable silicone composition comprises:
(A) an alkenyl group-containing organopolysiloxane having at least two alkenyl groups per molecule;
(B) an organohydrogenpolysiloxane including at least two silicon atom-bonded hydrogen atoms per molecule;
(C) silica;
(D) a high boiling point organic solvent having a boiling point of 100 °C or higher; and
(E) a curing catalyst.

### DETAILED DESCRIPTION

The following detailed description is merely exemplary in nature and is not intended to limit the disclosure or the application and uses of the subject matter as described herein. Furthermore, there is no intention to be bound by any theory presented in the preceding background or the following detailed description. It is to be appreciated that all values as provided herein, save for the actual examples or objective measurement parameters, are approximate values with endpoints or particular values intended to be read as “about” or “approximately” the value as recited.

The purpose of the present disclosure is to provide a curable silicone composition that is capable of forming a cured product having a low coefficient of thermal expansion.

As a result of diligent research carried out in order to solve the problem mentioned above, it was found that by adding a prescribed high boiling point organic solvent to a curable silicone composition, it was possible to lower the coefficient of thermal expansion of a cured product without increasing the viscosity of the composition, and thereby completed the present disclosure.

Therefore, the present disclosure relates to a curable silicone composition that contains:
(A) an alkenyl group-containing organopolysiloxane having at least two alkenyl groups per molecule;
(B) an organohydrogenpolysiloxane including at least two silicon atom-bonded hydrogen atoms per molecule;
(C) silica;
(D) a high boiling point organic solvent having a boiling point of 100 °C or higher; and
(E) a curing catalyst.

The content of the silica (C) is preferably 3-90 mass % based on the total mass of the curable silicone composition.

The high boiling point organic solvent of component (D) is preferably a non-polar organic solvent.

The high boiling point organic solvent of component (D) is preferably a hydrocarbon.

The alkenyl group-containing organopolysiloxane of component (A) is preferably an MQ resin-like organopolysiloxane.

The alkenyl group-containing organopolysiloxane of component (A) preferably includes two or more types of straight chain organopolysiloxane.

The curable silicone composition preferably further contains a white pigment as a component (F).

The present disclosure also relates to a reflective material for optical semiconductor devices, which comprises the curable silicone composition according to the present disclosure.

The present disclosure also relates to an optical semiconductor device provided with the reflective material for optical semiconductor devices according to the present disclosure.

The curable silicone composition according to the present disclosure is capable of forming a silicone cured product having a lower coefficient of thermal expansion.

The curable silicone composition according to the present disclosure relates to a curable silicone composition that contains:
(A) an alkenyl group-containing organopolysiloxane having at least two alkenyl groups per molecule;
(B) an organohydrogenpolysiloxane including at least two silicon atom-bonded hydrogen atoms per molecule;
(C) silica;
(D) a high boiling point organic solvent having a boiling point of 100 °C or higher; and
(E) a curing catalyst.

Preferably, the curable silicone composition of the present disclosure can achieve a low CTE when cured, and can therefore be advantageously used as a reflective material for optical semiconductor devices. Therefore, in a preferred embodiment, the curable silicone composition of the present disclosure is a white curable silicone composition in order to achieve high light reflectance when cured.

In addition, the curable silicone composition of the present disclosure can achieve a low CTE when cured, and can therefore be advantageously used as a sealing material for semiconductor elements.

The components of the curable silicone composition of the present disclosure are described in detail below.

### (A) Alkenyl Group-Containing Organopolysiloxane Having at Least Two Alkenyl Groups Per Molecule

Component (A) is a curable organopolysiloxane having at least two alkenyl groups per molecule. The curable silicone composition according to the present disclosure may contain one type of alkenyl group-containing organopolysiloxane (A) or two or more types of alkenyl group-containing organopolysiloxane (A).

Examples of the molecular structure of component (A) include straight chain, partially branched straight chain, branched chain, resin-like, cyclic, and three-dimensional network structures. Component (A) can be one organopolysiloxane having these molecular structures, or a mixture of two or more organopolysiloxanes having these molecular structures. In the present specification, the term resin-like means that the molecular structure has a branched or three-dimensional network structure. In one embodiment, the term resin-like means an organopolysiloxane in which the ratio of siloxane units (T units) represented by R—SiO_{3/2} and siloxane units (Q units) represented by SiO_{4/2} relative to all siloxane units in one molecule is 10% or more, preferably 20% or more, and more preferably 30% or more. In the present specification, R in a siloxane unit refers to a silicon atom-bonded organic group, for example a monovalent hydrocarbon group.

The curable silicone composition of the present disclosure preferably includes a resin-like alkenyl group-containing organopolysiloxane as component (A). In addition, the curable silicone composition of the present disclosure preferably includes a straight chain alkenyl group-containing organopolysiloxane as component (A). In addition, the curable silicone composition of the present disclosure preferably includes both a resin-like alkenyl group-containing organopolysiloxane and a straight chain alkenyl group-containing organopolysiloxane as component (A).

Examples of alkenyl groups contained in component (A) include alkenyl groups having 2-12 carbon atoms, such as vinyl groups, allyl groups, butenyl groups, pentenyl groups, hexenyl groups, heptenyl groups, octenyl groups, nonenyl groups, decenyl groups, undecenyl groups and dodecenyl groups, with vinyl groups being preferred.

Examples of silicon atom-bonded groups other than alkenyl groups contained in component (A) include halogen-substituted or unsubstituted monovalent hydrocarbon groups other than alkenyl groups, examples of which include alkyl groups having 1-12 carbon atoms, such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups and dodecyl groups; aryl groups having 6-20 carbon atoms, such as phenyl groups, tolyl groups, xylyl groups and naphthyl groups; aralkyl groups having 7-20 carbon atoms, such as benzyl groups, phenethyl groups and phenylpropyl groups; and groups in which some or all hydrogen atoms in these groups are substituted with halogen atoms such as fluorine atoms, chlorine atoms and bromine atoms. It should be noted that silicon atoms in component (A) may have a small amount of hydroxyl groups or alkoxy groups such as methoxy groups or ethoxy groups as long as the purpose of the present disclosure is not impaired. Silicon atom-bonded groups other than alkenyl groups in component (A) are preferably selected from among alkyl groups having 1-6 carbon atoms, and especially methyl groups.

In one embodiment of the present disclosure, component (A) can include a resin-like alkenyl group-containing organopolysiloxane as a component (A-1). The resin-like alkenyl group-containing organopolysiloxane (A-1) can preferably be represented by:

(R¹₃SiO_{1/2})ₐ(R¹₂SiO_{2/2})_{b}(R₁SiO_{3/2})_{c}(SiO_{4/2})_{d}(XO_{1/2})ₑ Average unit formula (I-a)

In formula (I-a), R₁ moieties may be the same as, or different from, each other, and are each a halogen-substituted or unsubstituted monovalent hydrocarbon group, but in one molecule, at least two R₁ moieties are alkenyl groups, and 0≤a<1, 0≤b<1, 0≤c<0.9, 0≤d<0.5, 0≤e<0.4, a+b+c+d=1.0, and c+d>0. e can denote the number of (XO) groups if the total number of silicon atoms is taken to be 1 (the ratio of the number of (XO) groups relative to the total number of silicon atoms). In addition, the value of c+d is preferably 0.1 or more, more preferably 0.2 or more, and further preferably 0.3 or more. In addition, in the present specification, a “unit formula” is a chemical formula that represents the proportion of siloxane units represented by (SiO_{x/2}) (x is an integer between 1 and 4) that are present, and a “structural formula” is a chemical formula that indicates the actual number of siloxane units per molecule.

Examples of halogen-substituted or unsubstituted monovalent hydrocarbon groups of R₁ in formula (I-a) above include alkyl groups having 1-12 carbon atoms, such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups and dodecyl groups; aryl groups having 6-20 carbon atoms, such as phenyl groups, tolyl groups, xylyl groups and naphthyl groups; aralkyl groups having 7-20 carbon atoms, such as benzyl groups, phenethyl groups and phenylpropyl groups; alkenyl groups having 2-12 carbon atoms, such as vinyl groups, allyl groups, butenyl groups, pentenyl groups, hexenyl groups, heptenyl groups, octenyl groups, nonenyl groups, decenyl groups, undecenyl groups and dodecenyl groups; and groups in which some or all hydrogen atoms in these groups are substituted with halogen atoms such as fluorine atoms, chlorine atoms and bromine atoms. R₁ may be a small amount of hydroxyl groups or alkoxy groups such as methoxy groups or ethoxy groups as long as the purpose of the present disclosure is not impaired. R₁ is preferably selected from among alkyl groups having 1-6 carbon atoms, and especially methyl groups, or alkenyl groups having 2-6 carbon atoms, and especially vinyl groups.

X in formula (I-a) above is a hydrogen atom or an alkyl group. Alkyl groups of X are preferably alkyl groups having 1-3 carbon atoms, with specific examples thereof including methyl groups, ethyl groups and propyl groups. X is preferably a hydrogen atom.

In formula (I-a) above, the value of a preferably falls within the range 0.1≤a≤0.8, more preferably falls within the range 0.2≤a≤0.7, and further preferably falls within the range 0.3≤a≤0.6. In formula (I-a) above, the value of b preferably falls within the range 0≤b≤0.5, more preferably falls within the range 0≤b≤0.3, and particularly preferably falls within the range 0≤b≤0.1. In formula (I-a) above, the value of c preferably falls within the range 0≤c≤0.5, more preferably falls within the range 0≤c≤0.3, and particularly preferably falls within the range 0≤c≤0.1. In formula (I-a) above, the value of d preferably falls within the range 0.1≤d≤0.8, more preferably falls within the range 0.2≤d≤0.7, and further preferably falls within the range 0.3≤d≤0.6. In formula (I-a) above, the value of e preferably falls within the range 0≤e≤0.15, more preferably falls within the range 0≤e≤0.1, and particularly preferably falls within the range 0≤e≤0.05.

In a preferred embodiment of the present disclosure, the resin-like alkenyl group-containing organopolysiloxane of component (A-1) includes a siloxane unit (Q unit) represented by R—SiO_{4/2}. The resin-like alkenyl group-containing organopolysiloxane of component (A-1) may or may not include, but preferably does not include, a siloxane unit (D unit) represented by R₂—SiO_{2/2}. In addition, the resin-like alkenyl group-containing organopolysiloxane of component (A-1) may or may not include, but preferably does not include, a siloxane unit (T unit) represented by R—SiO_{3/2}.

In a preferred embodiment of the present disclosure, the resin-like alkenyl group-containing organopolysiloxane of component (A-1) contains an alkenyl group at a molecular terminal. The resin-like organopolysiloxane of component (A-1) preferably has an alkenyl group in a siloxane unit (an M unit) represented by R₃—SiO_{1/2}, and may or may not include, but preferably does not include, an alkenyl group in a side chain of a molecular chain (that is, a siloxane unit (a D unit) represented by R₂—SiO_{2/2} and a siloxane unit (a T unit) represented by R—SiO_{3/2}).

In a preferred embodiment of the present disclosure, the resin-like alkenyl group-containing organopolysiloxane of component (A-1) includes an MQ resin-like alkenyl group-containing organopolysiloxane or comprises only an MQ resin-like alkenyl group-containing organopolysiloxane. An MQ resin-like organopolysiloxane is an organopolysiloxane comprising only siloxane units (M units) represented by R₃—SiO_{1/2} and siloxane units (Q units) represented by SiO_{4/2}. The MQ resin-like organopolysiloxane of component (A-1) can preferably be represented by average unit formula (I-b) below.

(R₁_{₃}SiO_{1/2})ₛ(SiO_{4/2})ₜ(XO_{1/2})ᵤ Average unit formula (I-b)

In the formula, R₁ moieties may be the same as, or different from, each other, and are each a halogen-substituted or unsubstituted monovalent hydrocarbon group, but in one molecule, at least two R₁ moieties are alkenyl groups, and 0<s<1, 0<t<1, 0≤u<0.4, s+t=1.0, and u denotes the number of (XO) groups if the total number of silicon atoms is taken to be 1 (the ratio of the number of (XO) groups relative to the total number of silicon atoms).

In formula (I-b), R₁ is as explained with respect to formula (I-a) above.

In formula (I-b), the value of s preferably falls within the range 0.2≤s≤0.8, more preferably falls within the range 0.3≤t≤0.7, and further preferably falls within the range 0.4≤s≤0.6. In formula (I-b), the value of t preferably falls within the range 0.2≤t≤0.8, more preferably falls within the range 0.3≤t≤0.7, and particularly preferably falls within the range 0.3≤t≤0.7. In formula (I-b), the value of u preferably falls within the range 0≤u≤0.3, more preferably falls within the range 0≤u≤0.2, and particularly preferably falls within the range 0≤u≤0.1.

The content of alkenyl groups relative to all silicon atom-bonded organic groups in the resin-like alkenyl group-containing organopolysiloxane of component (A-1) is not particularly limited, but can be, for example, 3 mol % or more, preferably 5 mol % or more, and more preferably 10 mol % or more, of the total amount of silicon atom-bonded organic groups, and can be 40 mol % or less, preferably 30 mol % or less, and more preferably 20 mol % or less, of the total amount of silicon atom-bonded organic groups. It should be noted that the content of alkenyl groups can be determined by using, for example, analysis methods such as Fourier transform infrared spectroscopy (FT-IR) or nuclear magnetic resonance (NMR), or by using the titration method described below. In the present specification, numerical ranges may be established using any combination of numerical range upper and lower limits.

An explanation will now be given of a method for quantitatively determining the amount of alkenyl groups in components using a titration method. The content of alkenyl groups in an organopolysiloxane component can be quantitatively determined with high accuracy by using a titration method that is commonly known as the Wijs method. The principles of this method are explained below. First, alkenyl groups in an organopolysiloxane raw material are subjected to an addition reaction with iodine monochloride as shown in formula (1). Next, excess iodine monochloride is reacted with potassium iodide in a reaction shown in formula (2), thereby releasing iodine. Next, the released iodine is titrated using a sodium thiosulfate solution.

CH₂═CH—+2ICl→CH₂I—CHCl—+ICl (excess) Formula (1)

ICl+KI→I₂+KCl Formula (2)

The amount of alkenyl groups in the component can be quantitatively determined from the difference between the amount of sodium thiosulfate required for the titration and the titration amount of a separately produced blank solution.

The MQ resin of component (A-1) can be a solid at ambient temperature (25 °C).

In a case where component (A) includes one or more types of resin-like organopolysiloxane (A-1), the content thereof is not particularly limited, but is preferably 1 mass % or more, more preferably 1.5 mass % or more, and further preferably 2 mass % or more, based on the total mass of the curable silicone composition of the present disclosure. In addition, the content of component (A-1) is preferably 20 mass % or less, more preferably 15 mass % or less, and further preferably 10 mass % or less, based on the total mass of the curable silicone composition. That is, in a case where component (A) includes one or more types of resin-like organopolysiloxane (A-1), the content thereof is 1-20 mass %, preferably 1.5-15 mass % or more, and more preferably 2-10 mass %, based on the total mass of the curable silicone composition of the present disclosure.

In another embodiment, in a case where component (A) includes one or more types of resin-like organopolysiloxane (A-1), the content thereof is preferably 2.5 mass % or more, more preferably 5 mass % or more, and further preferably 7.5 mass % or more, based on the total mass of the overall organopolysiloxane component of the present disclosure. In addition, the content of component (A-1) is preferably 40 mass % or less, more preferably 30 mass % or less, and further preferably 20 mass % or less, based on the total mass of the overall organopolysiloxane component. That is, in a case where component (A) includes one or more types of resin-like organopolysiloxane (A-1), the content thereof is 2.5-40 mass %, preferably 5-30 mass % or more, and more preferably 7.5-20 mass %, based on the total mass of the overall organopolysiloxane component of the present disclosure. It should be noted that in the present specification, the term “overall organopolysiloxane component” includes alkenyl group-containing organopolysiloxanes and organohydrogenpolysiloxanes.

Component (A) may include a straight chain alkenyl group-containing organopolysiloxane as a component (A-2). The straight chain alkenyl group-containing organopolysiloxane of component (A-2) can preferably be represented by:

R₁_{₃}SiO(R₁_{₂}SiO_{2/2})ₘSiR²₃ Average structural formula (I-c)

In formula (I-c), R₁ moieties may be the same as, or different from, each other, and are each a halogen-substituted or unsubstituted monovalent hydrocarbon group, but in one molecule, at least two R₁ moieties are alkenyl groups, and the value of m is 1-2000.

In formula (I-c) above, halogen-substituted or unsubstituted monovalent hydrocarbon groups of R₁ can be the same as those in formula (I-a) above.

In formula (I-c) above, m is preferably 25 to 1500, more preferably 50 to 1250, and further preferably 100 to 800.

Examples of component (A-2) include dimethylpolysiloxanes capped at both molecular terminals with dimethylvinylsiloxy groups, dimethylpolysiloxanes capped at both molecular terminals with diphenylvinylsiloxy groups, copolymers of dimethylpolysiloxanes capped at both molecular terminals with dimethylvinylsiloxy groups and methylphenylsiloxanes, copolymers of dimethylpolysiloxanes capped at both molecular terminals with dimethylvinylsiloxy groups and diphenylsiloxanes, copolymers of dimethylpolysiloxanes capped at both molecular terminals with diphenylvinylsiloxy groups and methylphenylsiloxanes, copolymers of dimethylpolysiloxanes capped at both molecular terminals with dimethylvinylsiloxy groups and methylvinylsiloxanes, copolymers of dimethylpolysiloxanes capped at both molecular terminals with dimethylvinylsiloxy groups, methylphenylsiloxanes and methylvinylsiloxanes, copolymers of dimethylpolysiloxanes capped at both molecular terminals with dimethylvinylsiloxy groups, diphenylsiloxanes and methylvinylsiloxanes, methylvinylpolysiloxanes capped at both molecular terminals with trimethylsiloxy groups, copolymers of methylvinylsiloxanes capped at both molecular terminals with trimethylsiloxy groups and methylphenylsiloxanes, copolymers of methylvinylsiloxanes capped at both molecular terminals with trimethylsiloxy groups and diphenylsiloxanes, and copolymers of dimethylsiloxanes capped at both molecular terminals with trimethylsiloxy groups and methylvinylsiloxanes.

In a preferred embodiment of the present disclosure, the straight chain alkenyl group-containing organopolysiloxane of component (A-2) can be a straight chain organopolysiloxane capped at both molecular terminals with alkenyl groups, which contains alkenyl groups at both molecular terminals. The straight chain organopolysiloxane of component (A-2) may or may not include, but preferably does not include, an alkenyl group in a side chain of a molecular chain (that is, a D unit).

The content of alkenyl groups contained in the straight chain organopolysiloxane of component (A-2) (the molar percentage of alkenyl groups relative to all silicon atom-bonded organic groups in the straight chain organopolysiloxane) can be designed according to need, but can generally fall within the range 0.1-20 mol %. It should be noted that the content of alkenyl groups can be determined by using, for example, analysis methods such as Fourier transform infrared spectroscopy (FT-IR), nuclear magnetic resonance (NMR), or the titration method described above.

In a preferred embodiment of the present disclosure, component (A) includes a combination of two or more types of straight chain organopolysiloxane (A-2). In a more preferred embodiment of the present disclosure, component (A) includes a combination of three types of straight chain organopolysiloxane (A-2).

In a case where component (A) includes a straight chain organopolysiloxane (A-2), the content thereof is not particularly limited, but can be preferably 5 mass % or more, more preferably 10 mass % or more, further preferably 15 mass % or more, and particularly preferably 18 mass % or more based on the total mass of the curable silicone composition of the present disclosure. In addition, the content of component (A-2) is preferably 50 mass % or less, more preferably 45 mass % or less, further preferably 40 mass % or less, and particularly preferably 35 mass % or less, based on the total mass of the curable silicone composition of the present disclosure. That is, in a case where component (A) includes one or more types of straight chain organopolysiloxane (A-2), the content thereof is 5-50 mass %, preferably 10-45 mass % or more, more preferably 15-40 mass %, and particularly preferably 18-35 mass %, based on the total mass of the curable silicone composition of the present disclosure.

In another embodiment, in a case where component (A) includes one or more types of straight chain organopolysiloxane (A-2), the content thereof is preferably 50 mass % or more, more preferably 60 mass % or more, further preferably 70 mass % or more, and particularly preferably 80 mass % or more, based on the total mass of the overall organopolysiloxane component of the present disclosure. In addition, the content of component (A-2) is preferably 97.5 mass % or less, more preferably 95 mass % or less, further preferably 92.5 mass % or less, and particularly preferably 90 mass % or less, based on the total mass of the overall organopolysiloxane component. That is, in a case where component (A) includes one or more types of straight chain organopolysiloxane (A-2), the content thereof is 50-97.5 mass %, preferably 60-95 mass % or more, more preferably 70-92.5 mass %, and particularly preferably 80-90 mass %, based on the total mass of the overall organopolysiloxane component of the present disclosure.

In one embodiment, component (A) includes a small quantity of an aryl group, or does not contain an aryl group, in a silicon atom-bonded organic group. Specifically, the amount of aryl groups relative to silicon atom-bonded organic groups can be 10 mol % or less, 5 mol % or less, 3 mol % or less, or 1 mol % or less.

In a case where the alkenyl group-containing organopolysiloxane (A) is a liquid at ambient temperature, the viscosity thereof is not particularly limited, but can be, for example, 5 mPa·s to 10 000 mPa·s, and preferably 10 mPa·s to 5000 mPa·s at 25 °C. In the present specification, the viscosity of the organopolysiloxane component can be measured using a B-type rotational viscometer in accordance with JIS K 7117-1.

The mass average molecular weight (Mw) of the alkenyl group-containing organopolysiloxane (A) is not particularly limited, but falls within a range of, for example, 1000 to 300 000, and preferably 1500 to 200 000. It should be noted that mass average molecular weight can be measured by GPC in the present specification.

In addition, the content of component (A) as a whole is not particularly limited, but is 10 mass % or more, preferably 15 mass % or more, and more preferably 20 mass % or more, based on the total mass of the curable silicone composition. In addition, component (A) can be contained at a quantity of 60 mass % or less, preferably 50 mass % or less, and more preferably 40 mass % or less, based on the total mass of the curable silicone composition. That is, the content of component (A) as a whole can be 10-60 mass %, 15-50 mass %, or 20-40 mass % based on the total mass of the curable silicone composition of the present disclosure.

### (B) Organohydrogenpolysiloxane Including at Least Two Silicon Atom-Bonded Hydrogen Atoms Per Molecule

Component (B) is an organohydrogenpolysiloxane including at least two silicon atom-bonded hydrogen atoms per molecule. The curable silicone composition according to the present disclosure may contain one type of organohydrogenpolysiloxane (B) or two or more types of organohydrogenpolysiloxane (B).

Examples of the molecular structure of component (B) include straight chain, partially branched straight chain, branched chain, resin-like, cyclic, and three-dimensional network structures. Component (B) can be one organopolysiloxane having these molecular structures, or a mixture of two or more organopolysiloxanes having these molecular structures.

Examples of silicon atom-bonded organic groups other than silicon atom-bonded hydrogen atoms contained in component (B) include halogen-substituted or unsubstituted monovalent hydrocarbon groups other than alkenyl groups, examples of which include alkyl groups having 1-12 carbon atoms, such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups and dodecyl groups; aryl groups having 6-20 carbon atoms, such as phenyl groups, tolyl groups, xylyl groups and naphthyl groups; aralkyl groups having 7-20 carbon atoms, such as benzyl groups, phenethyl groups and phenylpropyl groups; and groups in which some or all hydrogen atoms in these groups are substituted with halogen atoms such as fluorine atoms, chlorine atoms and bromine atoms. It should be noted that silicon atoms in component (B) may have a small amount of hydroxyl groups or alkoxy groups such as methoxy groups or ethoxy groups as long as the purpose of the present disclosure is not impaired. Silicon atom-bonded organic groups other than silicon atom-bonded hydrogen atoms in component (B) are preferably selected from among alkyl groups having 1-6 carbon atoms, and especially methyl groups.

The organohydrogenpolysiloxane of component (B) preferably includes a straight chain organohydrogenpolysiloxane. More preferably, the organohydrogenpolysiloxane of component (B) includes a straight chain organohydrogenpolysiloxane that includes a silicon atom-bonded hydrogen atom at both molecular chain terminals. This type of straight chain organohydrogenpolysiloxane has a silicon atom-bonded hydrogen atom at both molecular chain terminals, and preferably has a silicon atom-bonded hydrogen atom only at both molecular chain terminals. The straight chain organohydrogenpolysiloxane may or may not include, but preferably does not include, a silicon atom-bonded hydrogen atom in a molecular chain side chain (that is, a siloxane unit (D unit) represented by R₂—SiO_{2/2}). In addition, in one embodiment, the organohydrogenpolysiloxane of component (B) has two silicon atom-bonded hydrogen atoms per molecule.

In one embodiment, the organohydrogenpolysiloxane of component (B) can include a resin-like organohydrogenpolysiloxane. The resin-like organohydrogenpolysiloxane can preferably be represented by average unit formula (II) below:

(R₂_{₃}SiO_{1/2})ₐ(R₂_{₂}SiO_{2/2})_{b}(R₂SiO_{3/2})_{c}(SiO_{4/2})_{d}(XO_{1/2})ₑ Average unit formula (II)

In formula (II), R₂ moieties may be the same as, or different from, each other, and are each independently a hydrogen atom or a halogen-substituted or unsubstituted monovalent hydrocarbon group other than an alkenyl group, but in one molecule, at least two R₂ moieties are hydrogen atoms, and 0≤a<1, 0≤b<1, 0≤c<0.7, 0≤d<0.5, 0≤e<0.4, a+b+c+d=1.0, and c+d>0. e can denote the number of (XO) groups if the total number of silicon atoms is taken to be 1 (the ratio of the number of (XO) groups relative to the total number of silicon atoms)). In addition, the value of c+d is preferably 0.1 or more, more preferably 0.2 or more, and further preferably 0.3 or more.

Examples of halogen-substituted or unsubstituted monovalent hydrocarbon groups other than alkenyl groups of R₂ in formula (II) include alkyl groups having 1-12 carbon atoms, such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups and dodecyl groups; aryl groups having 6-20 carbon atoms, such as phenyl groups, tolyl groups, xylyl groups and naphthyl groups; aralkyl groups having 7-20 carbon atoms, such as benzyl groups, phenethyl groups and phenylpropyl groups; and groups in which some or all hydrogen atoms in these groups are substituted with halogen atoms such as fluorine atoms, chlorine atoms and bromine atoms. R₂ may be a small amount of hydroxyl groups or alkoxy groups such as methoxy groups or ethoxy groups as long as the purpose of the present disclosure is not impaired. R₂ is preferably selected from among hydrogen atoms and alkyl groups having 1-6 carbon atoms, and especially methyl groups.

X in formula (II) above is a hydrogen atom or an alkyl group. Alkyl groups of X are preferably alkyl groups having 1-3 carbon atoms, with specific examples thereof including methyl groups, ethyl groups and propyl groups. X is preferably a hydrogen atom.

In formula (II) above, the value of a preferably falls within the range 0.1≤a≤0.9, more preferably falls within the range 0.3≤a≤0.8, and further preferably falls within the range 0.5≤a≤0.7. In formula (II) above, the value of b preferably falls within the range 0≤b≤0.5, more preferably falls within the range 0≤b≤0.3, and particularly preferably falls within the range 0≤b≤0.1. In formula (II) above, the value of c preferably falls within the range 0.1≤c≤0.7, more preferably falls within the range 0.2≤c≤0.6, and particularly preferably falls within the range 0.3≤c≤0.5. In formula (II) above, the value of d preferably falls within the range 0≤d≤0.7, more preferably falls within the range 0≤d≤0.6, and particularly preferably falls within the range 0≤d≤0.5. In formula (II) above, the value of e preferably falls within the range 0≤e≤0.15, more preferably falls within the range 0≤e≤0.1, and particularly preferably falls within the range 0≤e≤0.05.

A preferred embodiment of the present disclosure may or may not include, but preferably does not include, a siloxane unit (D unit) represented by R₂SiO_{1/2}.

In a preferred embodiment of the present disclosure, the resin-like organohydrogenpolysiloxane of component (B) has a silicon atom-bonded hydrogen atom at a molecular terminal. The resin-like organohydrogenpolysiloxane of component (B) preferably has a silicon atom-bonded hydrogen atom in an M unit, and may or may not include, but preferably does not include, a silicon atom-bonded hydrogen atom in a molecular chain side chain (that is, a D unit and a T unit).

In one embodiment of the present disclosure, the organohydrogenpolysiloxane of component (B) can be an MT resin-like organohydrogenpolysiloxane comprising only M units and T units.

In a preferred embodiment, the organohydrogenpolysiloxane of component (B) includes at least one silicon atom-bonded aryl group in the molecule. In a case where component (B) contains an aryl group, the content thereof (the molar percentage of aryl groups relative to all silicon atom-bonded functional groups in the organohydrogenpolysiloxane) can be designed according to need, but it is generally 1 mol % or more, preferably 5 mol % or more, more preferably 10 mol % or more, further preferably 13 mol % or more, and particularly preferably 16 mol % or more, and can be 50 mol % or less, preferably 40 mol % or less, more preferably 35 mol % or less, further preferably 30 mol % or less, and particularly preferably 25 mol % or less.

In one embodiment of the present disclosure, if the organohydrogenpolysiloxane of component (B) contains an aryl group, the aryl group preferably includes an aryl group as a pendant group in a molecular side chain. The organohydrogenpolysiloxane of component (B) preferably has an aryl group in a siloxane unit (T unit) represented by RSiO_{3/2}. The organohydrogenpolysiloxane of component (B) may or may not include, but preferably does not include, an aryl group in a siloxane unit (M unit) represented by R₃SiO_{1/2}.

In addition, in one embodiment of the present disclosure, the organohydrogenpolysiloxane of component (B) is in a solid or liquid state at 25 °C, but is preferably a liquid. The viscosity of the organohydrogenpolysiloxane of component (B) is not particularly limited, but preferably falls within the range 1-100 000 mPa·s, more preferably falls within the range 2-50 000 mPa·s, and further preferably falls within the range 3-10 000 mPa·s at 25 °C and 20/s.

The content of component (B) is not particularly limited, but can generally be 0.5 mass % or more, and preferably 1 mass % or more, based on the total mass of the curable silicone composition of the present disclosure or the total mass of the overall organopolysiloxane component in the composition. In addition, the content of component (B) is generally 15 mass % or less, and can preferably be 10 mass % or less, based on the total mass of the curable silicone composition or the total mass of the overall organopolysiloxane component in the composition. That is, the content of component (B) can be 0.5-15 mass %, and preferably 1-10 mass %, based on the total mass of the curable silicone composition of the present disclosure or the total mass of the overall organopolysiloxane component in the composition.

In the curable silicone composition of the present disclosure, the molar ratio (H/Ak) of silicon atom-bonded alkenyl groups and silicon atom-bonded hydrogen atoms contained in the overall organopolysiloxane component can be such that the amount of silicon atom-bonded hydrogen atoms is 0.5-2.0 moles relative to 1 mole of silicon atom-bonded alkenyl groups. The molar ratio of silicon atom-bonded hydrogen atoms relative to 1 mole of silicon atom-bonded alkenyl groups contained in the organopolysiloxane component preferably falls within the range 0.7-1.5, and more preferably falls within the range 0.8-1.2.

In addition, the curable silicone composition of the present disclosure can contain a straight chain, branched chain, resin-like, three-dimensional network structure and/or cyclic organopolysiloxane as long as the advantageous effect of the present disclosure is not impaired.

### (C) Silica

The curable silicone composition according to the present disclosure contains silica as component (C). Component (C) may include one type of silica or a combination of two or more types of silica.

Examples of the form of the silica (C) include spherical, elliptical, flat, lamellar, flaky, needle-like, scaly, aggregated and polyhedral, but the silica is preferably spherical from the perspectives of enabling high density filling and suppressing an increase in viscosity.

Examples of the silica (C) include fumed silica, dry process silica, wet process silica, crystalline silica and precipitated silica. In addition, the silica may be subjected to a surface hydrophobization treatment using organic silicon compounds, such as organoalkoxysilane compounds, organochlorosilane compounds, organosilazane compounds and low molecular weight siloxane compounds, silane coupling agents, and titanate-based coupling agents.

The average particle diameter of the silica (C) is not particularly limited, but is preferably 3 μm to 50 μm, more preferably 5 μm to 40 μm, and further preferably 10 μm to 30 μm. It should be noted that in the present specification, the term “average particle diameter” means primary particle diameter and, more specifically, means the number-average average particle diameter (also referred to as median diameter), which is given by the statistical particle size distribution at half the population, and this is referred to as D50. For example, number-average average particle diameter can be measured using a laser diffraction type particle size distribution measurement apparatus.

The content of the silica (C) is not particularly limited, but is 3 mass % or more, more preferably 5 mass % or more, and particularly preferably 10 mass % or more, based on the total mass of the curable silicone composition. In addition, the content of the silica (C) is preferably 90 mass % or less, more preferably 85 mass % or less, and further preferably 80 mass % or less, based on the total mass of the curable silicone composition. That is, the content of the silica (C) is preferably 3-90 mass %, more preferably 5-85 mass %, and further preferably 10-80 mass %, based on the total mass of the curable silicone composition of the present disclosure.

In addition, in another embodiment, the content of the silica (C) is preferably 45 mass % or less, more preferably 35 mass % or less, and further preferably 30 mass % or less, based on the total mass of the curable silicone composition. That is, the content of the silica (C) is preferably 3-45 mass %, more preferably 5-35 mass %, and further preferably 10-30 mass %, based on the total mass of the curable silicone composition of the present disclosure.

### (D) High Boiling Point Organic Solvent Having a Boiling Point of 100 °C or Higher

The curable silicone composition according to the present disclosure contains a high boiling point organic solvent having a boiling point of 100 °C or higher as a component (D). Component (D) may include one type of high boiling point organic solvent or a combination of two or more types of high boiling point organic solvent.

Component (D) is a high boiling point organic solvent having a boiling point of 100 °C or higher at atmospheric pressure (1 atm), and preferably has a boiling point of 105 °C or higher. The upper limit of the boiling point of the high boiling point organic solvent is not particularly limited, that can be, for example, 350 °C or lower, preferably 300 °C or lower, more preferably 250 °C or lower and particularly preferably 230 °C or lower.

The high boiling point organic solvent (D) is not particularly limited, and organic solvents that are well known by persons skilled in the art can be used, but examples thereof include hydrocarbons, alcohols such as 1-butanol, 2-ethoxyethanol, 2-butoxyethanol, 1-hexanol, 2-methoxyethanol, 2-methyl-2-butanol, 3-methyl-1-butanol, 2-ethylhexanol, 1-octanol, 2-octanol, 1-pentanol, 3-pentanol, tetraethylene glycol, benzyl alcohol, ethylene glycol and diethylene glycol; ethers such as dibutyl ether, diethylene glycol dimethyl ether and triethylene glycol dimethyl ether; esters such as butyl acetate, ethylene carbonate, propylene carbonate, ethyl methyl carbonate, butyl acetate, diethyl carbonate, ethyl acetoacetate and isopentyl acetate; ketones such as methyl isobutyl ketone, diisobutyl ketone, cyclohexanone and acetophenone; amides such as N-methylpyrrolidone, N,N-dimethylformamide and N,N-dimethylacetamide, phenol compounds, and lactones.

The high boiling point organic solvent (D) is a polar solvent or a non-polar solvent, but is preferably a non-polar solvent. More specifically, the high boiling point organic solvent (D) is preferably a non-polar organic solvent constituted from carbon atoms and hydrogen atoms, and can therefore be selected from among hydrocarbons in particular, which are constituted from carbon atoms and hydrogen atoms. Examples of hydrocarbons include aromatic hydrocarbons such as xylene, toluene, styrene, cumene, durene, dodecylbenzene and naphthalene; and aliphatic hydrocarbons such as octane, nonane, decane, undecane, dodecane, tridecane, tetradecane, pentadecane, hexadecane, dodecene, decalin, n-paraffins, isoparaffins, turpentine oil, kerosene and light oil.

The content of the high boiling point organic solvent (D) is preferably 0.1 mass % or more, more preferably 0.3 mass % or more, and particularly preferably 0.5 mass % or more, based on the total mass of the curable silicone composition. In addition, the high boiling point organic solvent (D) can be contained at a quantity of 20 mass % or less, preferably 15 mass % or less, and more preferably 10 mass % or less, based on the total mass of the curable silicone composition. That is, the content of the high boiling point organic solvent (D) can be 0.1-20 mass %, preferably 0.3-15 mass %, and 0.5-10 mass %, based on the total mass of the curable silicone composition of the present disclosure.

### (E) Curing Catalyst

The curing catalyst of component (E) is a hydrosilylation reaction curing catalyst, which is a catalyst for promoting curing of the curable silicone composition of the present disclosure. Examples of this component (E) include platinum-based catalysts such as chloroplatinic acid, alcohol solutions of chloroplatinic acid, complexes of platinum and olefins, complexes of platinum and 1,3-divinyl-1,1,3,3-tetramethyldisiloxane, and platinum-supporting powders; palladium-based catalysts such as tetrakis(triphenyl phosphine) palladium, palladium black and mixtures of palladium and triphenylphosphine; and rhodium-based catalysts, with platinum-based catalysts being particularly preferred.

The blending quantity of component (E) is a catalytic amount and, more specifically, in a case where a platinum-based catalyst is used as component (E), the amount of platinum atoms is preferably 0.01 ppm or more, more preferably 0.1 ppm or more, and further preferably 1 ppm or more, relative to the total mass of the curable silicone composition of the present disclosure, and is preferably 50 ppm or less, more preferably 40 ppm or less, and further preferably 35 ppm or less, relative to the total mass of the curable silicone composition of the present disclosure.

### Other Components

Optional components can be blended in the curable silicone composition of the present disclosure as long as the purpose of the present disclosure is not impaired. Examples of these optional components include white pigments, inorganic fillers other than the silica (C) and white pigments, acetylene compounds, organic phosphorus compounds, vinyl group-containing siloxane compounds, hydrosilylation reaction inhibitors, organopolysiloxanes not containing silicon atom-bonded hydrogen atoms or silicon atom-bonded alkenyl groups, tackifiers, surface treatment agents for powders, antioxidants such as cerium-containing siloxanes, heat resistance-imparting agents, cold resistance-imparting agents, thermally conductive fillers, flame retardancy-imparting agents, thixotropy-imparting agents, fluorescent materials and solvents. Such optional components are generally added at a quantity of 0.001-20 mass % of the overall composition.

In a case where the curable silicone composition according to the present disclosure is used as a reflective material, the curable silicone composition preferably contains a white pigment as a component (F) in order to increase the reflectance of the cured product.

Examples of white pigments include metal oxides such as titanium oxide, aluminum oxide, zinc oxide, zirconium oxide and magnesium oxide; hollow fillers such as glass balloons and glass beads; and others such as barium sulfate, zinc sulfate, barium titanate, aluminum nitride, boron nitride and antimony oxide. Titanium oxide is preferred from the perspectives of exhibiting high light reflectance and opacity.

The white pigment may be further subjected to a surface treatment in order to increase reflectance, whiteness and lightfastness. Types of surface treatment include well-known surface treatments, such as treating with aluminum oxide, aluminum hydroxide, silica, zinc oxide, zirconium oxide, organic compounds and siloxanes. Organic compounds are not particularly limited, but examples thereof include polyhydric alcohols, alkanolamines and derivatives thereof, organic silicon compounds such as organic siloxanes, higher fatty acids and metal salts thereof, and organometallic compounds. The surface treatment method is not particularly limited as long as this is a well-known method, and it is possible to use methods such as (1) a method comprising blending a white pigment that has been surface treated in advance in the silicone composition, or (2) a method comprising adding a surface treatment agent other than a white pigment to the silicone composition and reacting with the white pigment in the composition.

The surface treatment of the white pigment is not particularly limited as long as this is a well-known type, but a treatment that does not include silica is particularly preferred from the perspective that an obtained white cured product exhibits particularly excellent lightfastness. Furthermore, a treatment that does not include an organic substance treatment is particularly preferred from the perspective that an obtained white cured product can maintain high reflectance after a heat resistance test. The surface treatment of the white pigment can be analyzed by using an analysis method such as energy dispersion type X-ray spectroscopy (SEM-EDX) or inductively coupled plasma mass spectrometry (ICP-MS).

The average particle diameter of the white pigment (F) is not particularly limited, but is preferably 0.05 μm to 3 μm, and more preferably 0.1 μm to 1 μm. It should be noted that in the present specification, the term “average particle diameter” means primary particle diameter and, more specifically, means the number-average average particle diameter (also referred to as median diameter), which is given by the statistical particle size distribution at half the population, and this is referred to as D50. For example, number-average average particle diameter can be measured using a laser diffraction type particle size distribution measurement apparatus.

In a case where the curable silicone composition of the present disclosure contains the white pigment (F), the content of the white pigment (F) is not particularly limited, but is, for example, 10 mass % or more, more preferably 20 mass % or more, and particularly preferably 30 mass % or more, based on the total mass of the curable silicone composition. In addition, the white pigment (F) can be contained at a quantity of preferably 70 mass % or less, more preferably 60 mass % or less, and further preferably 50 mass % or less, based on the total mass of the curable silicone composition. That is, the content of the white pigment (F) is preferably 10-70 mass %, more preferably 20-60 mass %, and further preferably 30-50 mass %, based on the total mass of the curable silicone composition of the present disclosure.

Examples of inorganic fillers other than the silica (C) and the white pigment (F) include magnesium carbonate, zinc oxide, iron oxide, diatomaceous earth, and the like, as well as inorganic fillers obtained by subjecting the surface of the aforementioned inorganic fillers to a hydrophobization treatment using an organic silicon compound.

In one embodiment of the present disclosure, the content of inorganic fillers including the silica (C) and the white pigment (F) in the curable silicone composition of the present disclosure is preferably 3-80 mass %, more preferably 5-75 mass %, and further preferably 10-70 mass %, based on the total mass of the curable silicone composition. In addition, in one embodiment, the total amount of the silica (C) and the white pigment (F) in the curable silicone composition of the disclosure is preferably 3-80 mass %, more preferably 5-75 mass %, and further preferably 10-70 mass %, based on the total mass of the curable silicone composition.

Examples of reaction inhibitors include hydrosilylation reaction inhibitors that inhibit a hydrosilylation reaction of the organopolysiloxane component of the present disclosure. Examples of such curing reaction inhibitors include: alkyne alcohols such as 2-methyl-3-butyn-2-ol, 3,5-dimethyl-1-hexyn-3-ol, 2-phenyl-3-butyn-2-ol, 1-ethynyl-1-cyclohexanol and 1-ethynyl-2-cyclohexanol; enyne compounds such as 3-methyl-3-penten-1-yne and 3,5-dimethyl-3-hexen-1-yne; alkenyl group-containing low molecular weight siloxanes such as tetramethyltetravinylcyclotetrasiloxane and tetramethyltetrahexenylcyclotetrasiloxane; alkynyloxysilanes such as methyl-tris(1,1-dimethylpropynyloxy)silane, vinyl-tris(1,1-dimethylpropynyloxy)silane and methyl-tris-(3-methyl-1-butyn-3-oxy)silane; maleic acid esters such as diallyl maleate and bis(2-ethylhexyl) maleate; and disulfide compounds having a disulfide structure, such as di-dodecyl disulfide, di-decyl disulfide and di-octyl disulfide. The hydrosilylation reaction inhibitor is preferably selected from among alkyne alcohols and maleic acid esters and, in particular, preferably includes an alkyne alcohol and a maleic acid ester. The reaction inhibitor is generally added at a quantity of 0.001-5 mass % of the overall composition.

Powder surface treatment agents are not particularly limited, but examples thereof include organosilazanes, organocyclosiloxanes, organochlorosilanes, organoalkoxysilanes such as 7-octenyltrimethoxysilane, N-2-(aminoethyl)-8-aminooctyltrimethoxysilane, 8-methacryloxyoctyltrimethoxysilane and 8-glycidoxyoctyltrimethoxysilane, low molecular weight straight chain siloxanes, and organic compounds. Examples of organic compounds include polyhydric alcohols, alkanolamines and derivatives thereof, organosilicon compounds such as organic siloxanes, higher fatty acids and metal salts thereof, organometallic compounds, organometallic complexes, fluorine-based organic compounds, anionic surfactants, cationic surfactants, and non-ionic surfactants. The powder surface treatment agent is generally added at a quantity of 0.001-5 mass % of the overall composition.

Examples of tackifiers include methyltrimethoxysilane, vinyltrimethoxysilane, aryltrimethoxysilanes, 3-glycidoxypropylmethyldiethoxysilane, 3-methacryloxypropyltrimethoxysilane, 3-glycidoxypropyltrimethoxysilane, 3-aminopropyltrimethoxysilane, N-(2-aminoethyl)-3-aminopropyltrimethoxysilane, bis(trimethoxysilyl)propane, bis(trimethoxysilyl)hexane, and similar silane coupling agents; tetraethyl titanate, tetrapropyl titanate, tetrabutyl titanate, tetra(2-ethylhexyl) titanate, titanium ethylacetonate, titanium acetylacetonate, and similar titanium compounds; aluminum ethylacetoacetate diisopropylate, aluminum tris(ethylacetoacetate), aluminum alkylacetoacetate diisopropylates, aluminum tris(acetylacetonate), aluminum monoacetylacetonate bis(ethylacetoacetate), and similar aluminum compounds; and zirconium acetylacetonate, zirconium butoxyacetylacetonate, zirconium bis(acetylacetonate), zirconium ethylacetoacetate, and similar zirconium compounds. The tackifier is generally added at a quantity of 0.001-5 mass % of the overall composition.

The curable silicone composition according to the present disclosure can be cured by heat to form a cured product. For example, as curing conditions, a curing process can be carried out at a temperature of 100-200 °C for a period of 10-180 minutes. In addition, electrically conductive metals such as silver, gold and copper; electrically non-conductive metals such as aluminum and nickel; and inorganic materials such as ceramics, such as aluminum nitride, as well as organic materials such as epoxy resins, BT resins, polyimide resins and silicone resins, can all exhibit excellent adhesive properties as adherends.

The curable silicone composition of the present disclosure can be prepared by mixing each component. The method for mixing the components is not particularly limited and can be a conventional well-known method, but the curable silicone composition can be prepared by mixing the components using a mixing device. Such mixing devices are not particularly limited, but examples thereof include single-screw and twin-screw continuous mixers, double roller mixers, Ross mixers, Hobart mixers, dental mixers, planetary mixers, kneader mixers and Henschel mixers.

### Reflective Material for Optical Semiconductor Device

The present disclosure also relates to a reflective material for optical semiconductor devices, which can be obtained by curing the curable white silicone composition of the present disclosure. The reflective material for optical semiconductor devices of the present disclosure is obtained by curing the curable white silicone composition of the present disclosure, and therefore exhibits excellent toughness. Optical semiconductor devices are not particularly limited, but examples thereof include light emitting diodes (LEDs), semiconductor lasers, photodiodes, phototransistors, solid-state imaging devices, and light emitters and light receivers for photocouplers, with light emitting diodes (LEDs) being particularly preferred.

### Optical Semiconductor Device

The optical semiconductor device of the present disclosure is provided with the reflective material for optical semiconductor devices of the present disclosure. Examples of such optical semiconductor devices include light emitting diodes (LEDs), semiconductor lasers, photodiodes, phototransistors, solid-state imaging devices, and light emitters and light receivers for photocouplers, with light emitting diodes (LEDs) being particularly preferred.

Specific embodiments of the present disclosure are presented below.

Embodiment 1: A curable silicone composition that contains: (A) an alkenyl group-containing organopolysiloxane having at least two alkenyl groups per molecule;
(B) an organohydrogenpolysiloxane including at least two silicon atom-bonded hydrogen atoms per molecule;
(C) silica;
(D) a high boiling point organic solvent having a boiling point of 100 °C or higher; and
(E) a curing catalyst.

Embodiment 2: The curable silicone composition according to embodiment 1, wherein the content of the silica (C) is 3-90 mass % based on the total mass of the curable silicone composition.

Embodiment 3: The curable silicone composition according to embodiment 1 or 2, wherein the high boiling point organic solvent of component (D) is a non-polar organic solvent.

Embodiment 4: The curable silicone composition according to any one of embodiments 1 to 3, wherein the high boiling point organic solvent of component (D) is a hydrocarbon.

Embodiment 5: The curable silicone composition according to any one of embodiments 1 to 4, wherein the alkenyl group-containing organopolysiloxane of component (A) includes an MQ resin-like organopolysiloxane.

Embodiment 6: The curable silicone composition according to any one of embodiments 1 to 5, wherein the alkenyl group-containing organopolysiloxane of component (A) includes two or more types of straight chain organopolysiloxane.

Embodiment 7: The curable silicone composition according to any one of embodiments 1 to 6, which further includes a white pigment as component (F).

Embodiment 8: A reflective material for optical semiconductor devices, which comprises a cured product of the curable silicone composition according to any one of embodiments 1 to 7.

Embodiment 9: An optical semiconductor device comprising the reflective material for optical semiconductor devices according to embodiment 8.

### EXAMPLES

The curable silicone composition of the present disclosure will be explained in greater detail through the use of working examples and comparative examples shown below.

Curable silicone compositions were prepared by mixing components according to formulations (parts by mass) shown in the tables. It should be noted that hereinafter, Me denotes a methyl group, Vi denotes a vinyl group, and Ph denotes a phenyl group. In addition, structures of organopolysiloxane components in tables are shown in a simplified form, and text within parentheses shows organic groups other than Me in M, D, T and Q units. In addition, H/Vi denotes the molar ratio of silicon atom-bonded hydrogen atoms (H) and vinyl groups (Vi) in organopolysiloxane components.
Component a-1: MQ resin-like alkenyl group-containing organopolysiloxane represented by average unit formula (Me₂ ViSiO_{1/2})₇(Me₃SiO_{1/2})₄₁(SiO_{4/2})₄₅₂OH)₄
Component a-2: Straight chain alkenyl group-containing organopolysiloxane represented by average structural formula ViMe₂SiO(Me₂SiO)₇₁₈SiViMe₂
Component a-3: Straight chain alkenyl group-containing organopolysiloxane represented by average structural formula ViMe₂SiO(Me₂SiO)₂₃₅SiViMe₂
Component a-4: Straight chain alkenyl group-containing organopolysiloxane represented by average structural formula ViMe₂SiO(Me₂SiO)₁₉₆SiViMe₂
Component b: Resin-like organohydrogenpolysiloxane represented by average unit formula (HMe₂SiO_{1/2})₆₀(PhSiO_{3/2})₄₀; molecular weight: 750
Component c-1: Silica (D50: 17 μm)
Component c-2: Titanium oxide (D50: 0.28 μm)
Component d-1: Isoparaffin-based solvent (product name: IP 2028, produced by Idemitsu Kosan Co., Ltd.; boiling point 213 °C)
Component d-2: Isoparaffin-based solvent (product name: IP 2028, produced by ENEOS; boiling point 173 °C)
Component d-3: Toluene; boiling point 110 °C.
Component e: Complex of platinum and divinyltetramethyldisiloxane having a platinum concentration of 3.0 mass %
Component f: 7-octenyltrimethoxysilane
Component g: 3-glycidoxypropylmethyldiethoxysilane
Component h: 1-ethynyl-1-cyclohexanol
Component i: Cerium-containing siloxane

### Evaluations

An obtained curable silicone composition was press molded at 150 °C for 15 minutes, and then cured at 150 °C for 1 hour and 45 minutes to obtain a cured product. The obtained cured product was subjected to the following evaluation tests.

### Coefficient of Linear Thermal Expansion (CTE)

A test piece (sample size: 15 mm×5 mm×5 mm) for measuring coefficient of linear thermal expansion (CTE) was prepared from an obtained cured product, and a TMA/SS7100 produced by Hitachi High-Technologies was used to determine the average coefficient of linear thermal expansion per unit temperature within the temperature range 10-140 °C when the temperature was increased from −50 °C to 180 °C at a temperature increase rate of 3 °C/min in a nitrogen atmosphere.

### Tensile Strength and Elongation

A tensile test was carried out in accordance with ASTM D412 (A method). For each test, three prescribed dumbbell-shaped test pieces were prepared, and an Autograph produced by Shimadzu Corporation was used to measure tensile strength (MPa) and breaking elongation (%) at a speed of 500±50 mm/min. Results were taken to be the average value of three tests.

### Viscosity

For the curable silicone compositions of Working Example 1 and Comparative Example 1, the viscosity at 25 °C was measured in accordance with the method described in JIS K 7117-1:1999 using a rheometer (MCR-302 produced by Anton Paar GmbH, parallel plate D-PP25; speed of rotation: 1/s). The curable silicone composition of Working Example 1 had a viscosity of 8 Pas, and could therefore be used in dispensing applications. Meanwhile, the curable silicone composition of Comparative Example 1 had a viscosity of 11 Pas, which is too high for dispensing applications, and was therefore unsuitable for dispensing applications. The results are shown in the tables below:

TABLE 1

| | Working | Working | Working | Working | Working | Working |
|---|---|---|---|---|---|---|
| | Example | Example | Example | Example | Example | Example |
| | 1 | 2 | 3 | 4 | 5 | 6 |
| Component | | | | | | |
| a-1: M(Vi)₇M₄₁Q₅₂(OH)₅ | 3 | 3 | 3 | 3 | 3 | 3 |
| a-2: M(Vi)D₇₁₈M(Vi) | 3 | 3 | 3 | 3 | 3 | 3 |
| a-3: M(Vi)D₂₃₅M(Vi) | 17 | 17 | 17 | 17 | 17 | 17 |
| a-4: M(Vi)D₁₉₆M(Vi) | 7.4 | 7.4 | 7.4 | 7.4 | 7.4 | 7.4 |
| b: M(H)₆₀T(Ph)₄₀ | 1.5 | 1.5 | 1.5 | 1.5 | 1.5 | 1.5 |
| c-1: Silica | 24 | 24 | 24 | 24 | 24 | 24 |
| c-2: Titanium oxide | 43 | 43 | 43 | 43 | 43 | 43 |
| d-1: Isoparaffin | 1 | 2 | 3 | 8 | — | — |
| (boiling point 213 °C) | | | | | | |
| d-2: Isoparaffin | — | — | — | — | 3 | — |
| (boiling point 173 °C) | | | | | | |
| d-3: Toluene | — | — | — | — | — | 3 |
| (boiling point 110 °C) | | | | | | |
| e: Pt catalyst | 0.015 | 0.015 | 0.015 | 0.015 | 0.015 | 0.015 |
| f | 0.4 | 0.4 | 0.4 | 0.4 | 0.4 | 0.4 |
| g | 0.5 | 0.5 | 0.5 | 0.5 | 0.5 | 0.5 |
| h | 0.1 | 0.1 | 0.1 | 0.1 | 0.1 | 0.1 |
| i | 0.085 | 0.085 | 0.085 | 0.085 | 0.085 | 0.085 |
| Filler content (wt %) | 67 | 67 | 67 | 67 | 67 | 67 |
| Total | 100 | 100 | 100 | 100 | 100 | 100 |
| Evaluation | | | | | | |
| CTE (ppm/°C) | 151 | 142 | 131 | 134 | 149 | 145 |
| Elongation (%) | 103 | 114 | 115 | 135 | 104 | 100 |
| Tensile strength (MPa) | 6.3 | 6.2 | 5.9 | 4.9 | 5.5 | 6.3 |

TABLE 2

| | Comparative | Comparative | Comparative |
|---|---|---|---|
| Component | Example 1 | Example 2 | Example 3 |
| a-1: M(Vi)₇M₄₁Q₅₂(OH)₅ | 3 | 9 | 9 |
| a-2: M(Vi)D₇₁₈M(Vi) | 3 | 9 | 9 |
| a-3: M(Vi)D₂₃₅M(Vi) | 17 | 52 | 52 |
| a-4: M(Vi)D₁₉₆M(Vi) | 7.4 | 24.9 | 24.9 |
| b: M(H)₆₀T(Ph)₄₀ | 1.5 | 4 | 4 |
| c-1: Silica | 24 | — | — |
| c-2: Titanium oxide | 43 | — | — |
| d-1: Isoparaffin (boiling | — | — | 3 |
| point 213 °C) | | | |
| e: Pt catalyst | 0.015 | 0.015 | 0.015 |
| f | 0.4 | 0.4 | 0.4 |
| g | 0.5 | 0.5 | 0.5 |
| h | 0.1 | 0.1 | 0.1 |
| i | 0.085 | 0.085 | 0.085 |
| Filler content (wt %) | 67 | 0 | 0 |
| Total | 100 | 100 | 100 |
| Evaluation | | | |
| CTE (ppm/°C) | 164 | 306 | 315 |
| Elongation (%) | 98 | 269 | 262 |
| Tensile strength (MPa) | 6.6 | 0.9 | 0.9 |

As can be understood from the results above, the curable silicone compositions of Working Examples 1-6 of the present disclosure contain a prescribed high boiling point organic solvent, and could therefore lower the coefficient of thermal expansion of a cured product. In addition, the tensile strength and elongation properties of Working Examples 1-6 of the present disclosure also fell within ranges suitable for substrate materials and sealing materials. The curable silicone compositions of Working Examples 1-6 of the present disclosure contain a high boiling point solvent, and could therefore achieve a low coefficient of thermal expansion even if the content of an inorganic filler is increased, meaning that the fluidity of the curable silicone composition could be maintained, and it can therefore be said that it is possible to effectively lower the coefficient of thermal expansion of the cured product without compromising handling and moldability at the time of curing and molding.

Meanwhile, the curable silicone composition of Comparative Example 1 contained silica at the same quantity as Working Examples 1-6, but did not contain the high boiling point organic solvent of component (D), and did not therefore exhibit a sufficiently low CTE if compared with the working examples in the present application. In addition, the viscosity was relatively high, which was unsuitable for dispensing applications, as mentioned above. In addition Comparative Examples 2 and 3 did not contain the silica (C) and/or the high boiling point organic solvent (D), and did not therefore exhibit a sufficiently low CTE.

TABLE 3

| | Working | Comparative |
|---|---|---|
| Component | Example 7 | Example 4 |
| a-1: M(Vi)₇M₄₁Q₅₂(OH)₅ | 2 | 2 |
| a-3: M(Vi)D₂₃₅M(Vi) | 11 | 11 |
| a-4: M(Vi)D₁₉₆M(Vi) | 7 | 7 |
| b: M(H)₆₀T(Ph)₄₀ | 2 | 2 |
| c-1: Silica | 78 | 78 |
| d-1: Isoparaffin (boiling point 213 °C) | 3 | — |
| e: Pt catalyst | 0.015 | 0.015 |
| f | 0.4 | 0.4 |
| g | 0.5 | 0.5 |
| h | 0.1 | 0.1 |
| i | 0.085 | 0.085 |
| Filler content (wt %) | 78 | 78 |
| Total | 100 | 100 |
| Evaluation | | |
| CTE (ppm/°C) | 56 | 77 |
| Elongation (%) | 31 | 27 |
| Tensile strength (MPa) | 6.6 | 7.0 |

Working Example 7 and Comparative Example 4 are examples of curable silicone compositions in which a high quantity of silica was filled. As can be understood from the results above, the curable silicone composition of Working Example 7 of the present disclosure contains a prescribed high boiling point organic solvent, and could therefore lower the coefficient of thermal expansion of a cured product to a greater extent than the curable silicone composition of Comparative Example 4, which contained the same amount of silica.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the present disclosure in any way. Rather, the foregoing detailed description will provide those skilled in the art with a convenient road map for implementing an exemplary embodiment of the present disclosure. It being understood that various changes may be made in the function and arrangement of elements described in an exemplary embodiment without departing from the scope of the present disclosure as set forth in the appended claims.

What is claimed is:

1. A curable silicone composition comprising:
(A) an alkenyl group-containing organopolysiloxane having at least two alkenyl groups per molecule;
(B) an organohydrogenpolysiloxane including at least two silicon atom-bonded hydrogen atoms per molecule;
(C) silica;
(D) a high boiling point organic solvent having a boiling point of 100 °C or higher; and
(E) a curing catalyst.

2. The curable silicone composition according to claim 1, wherein the content of the silica (C) is from 3-90 mass % based on the total mass of the curable silicone composition.

3. The curable silicone composition according to claim 1, wherein the high boiling point organic solvent of component (D) is a non-polar organic solvent.

4. The curable silicone composition according to claim 1, wherein the high boiling point organic solvent of component (D) is a hydrocarbon.

5. The curable silicone composition according to claim 1, wherein the alkenyl group-containing organopolysiloxane of component (A) includes an MQ resin-like organopolysiloxane.

6. The curable silicone composition according to claim 1, wherein the alkenyl group-containing organopolysiloxane of component (A) includes two or more types of straight chain organopolysiloxane.

7. The curable silicone composition according to claim 1, further comprising a white pigment as a component (F).

8. A reflective material for optical semiconductor devices, comprising a cured product of the curable silicone composition according to claim 1.

9. An optical semiconductor device comprising the reflective material for optical semiconductor devices according to claim 8.
